(19) United States
(12) Patent Application Publication
(10) Pub. No.: US 2015/0212138 A1
(43) Pub. Date: Jul. 30, 2015

(54) METHOD FOR DETECTING OPEN-CIRCUIT FAULTS IN ELECTRIC POWER DISTRIBUTION SYSTEM, AND POWER DISTRIBUTION FACILITIES MANAGEMENT SYSTEM

(71) Applicant: Hitachi, Ltd., Tokyo (JP)

(72) Inventors: Kazutoshi Tsuchiya, Tokyo (JP); Kenichiro Yamane, Tokyo (JP); Masahiro Adachi, Hitachi (JP); Mitsugu Daino, Osaka (JP)

(21) Appl. No.: 14/419,482

(22) PCT Filed: Jul. 22, 2013
(86) PCT No.: PCT/JP2013/069766

§ 371 Date: Feb. 4, 2015

(30) Foreign Application Priority Data
Aug. 8, 2012 (JP) 2012-175764

(51) Int. Cl. G01R 31/02; H02J 13/00; G01R 21/133

(52) U.S. Cl. CPC G01R 31/02; G01R 21/133; H02J 13/00

(57) ABSTRACT

An open-circuit fault in an electric power distribution line is detected using metering devices each having a communication function and each placed on a power consumer's circuit connected to an electric power distribution system, and a location of the open circuit is identified. An electric power distribution facilities management system obtains, from the power distribution system to which are connected consumers each including a sensor provided with a communication function, meter-reading data within each of the sensors having a communication function, via a communication system. The system includes a number-of-unavailable-data calculation unit that calculates a number of unavailable meter-reading data from the sensors having a communication function, an on-fault number-of-unavailable-data calculation unit that calculates the number of sensors each having a communication function and each placed in the power distribution system, and a fault determining unit that determines whether an open-circuit fault is occurring in the power distribution system.

### TECHNICAL FIELD

The present invention relates to methods for detecting open-circuit faults of power distribution line in an electric power distribution system and identifying locations of the open circuit. The invention also relates to systems for managing electric power distribution facilities.

### BACKGROUND ART

An open-circuit fault in an electric power distribution system is likely to lead to an accident from electrical shock due to human contact with the open-circuit of the power line. It becomes vital, therefore, to detect the open-circuit fault early from a perspective of safety of the power distribution system.

An open-circuit fault in such a power distribution line, however, is difficult to detect. For example, since the distribution line is insulated, the line often fails to form an electrical path to the ground even after sagging down to the ground surface. In this case, the open-circuit fault may not be detectable since the distribution system voltage and current will remain unchanged from respective values that they exhibit under normal conditions.

For these reasons, adopting a variety of sensor-aided methods to detect open-circuit faults has been considered. The open-circuit fault detection system described in Patent Document 1, for example, includes a plurality of meters that each have a communication function, meter the amount of electrical energy supplied from a power distribution line, and include a communication unit that transmits the metered data. The system also includes a management office capable of receiving the data transmitted from the meters having a communication function. The meters are placed on the distribution line, and they, detect a voltage of the distribution line. A location of an open-circuit on the distribution line is determined from a detection result on that voltage.

### PRIOR ART DOCUMENTS

### Patent Document

Patent Document 1: JP-2007-282452-A

### SUMMARY OF THE INVENTION

### Problem to be Solved by the Invention

The art relating to Patent Document 1, however, makes it necessary to place a plurality of additional meters (sensors) an the distribution line in order to detect an open-circuit fault in the distribution line, which poses a problem of increased equipment investments in distribution facilities management. In addition, where a synchronous generator, an induction generator, and the like are interconnected in or to the distribution system, even after an open-circuit fault has occurred, voltage may not exhibit an abnormal value, in which case the open-circuit fault becomes difficult to detect.

The present invention has been made for solving the above problem, and an object of the invention is to detect an open-circuit fault in an electric power distribution line by use of metering devices (Advanced Meter Infrastructure: AMI) each having a communication function and each placed on a power consumer's circuit connected to an electric power distribution system, and identify a location of the open-circuit.

### Means for Solving the Problem

To solve the above problem, an open-circuit fault detecting method and electric power distribution facilities management system according to the present invention adopts, for example, any one of configurations set forth in CLAIMS accompanying this patent application.

The open-circuit fault detecting method according to claim 1 includes placing sensors, each provided with a communication function, on a consumer connected to an electric power distribution system, and obtaining, via a communication system, meter-reading data detected by the sensors having a communication function; the detecting method further including detecting an open-circuit in the power distribution system in accordance with an unavailable state of the meter-reading data.

In addition, the power distribution system is divided into an appropriate number of sections. The number of those sensors with a communication function each reporting unavailability of meter-reading data in a corresponding section is compared with the number of those sensors with a communication function placed in the corresponding section, thereby determining whether an open circuit has occurred in the electric power distribution system.

In addition, a number of simultaneously unavailable data due to communication trouble is retrieved and retained from a past history, and the detection of the open circuit in the power distribution system is performed when the number of those sensors with a communication function that report the data unavailability is greater than the number of simultaneously unavailable data due to communication trouble.

Furthermore, the sections of the power distribution system are changed in order, thereby successively determining for each sections whether an open circuit has occurred in the electric power distribution system.

Moreover, the unavailable state of the meter-reading data includes a state in which the amount of meter-reading data detected by at least one of the sensors having a communication function is zero.

The electric power distribution facilities management system according to claim 7 obtains, from a power distribution system to which consumers each including a sensor provided with a communication function are connected, meter-reading data within each of the sensors having a communication function, via a communication system. The power distribution facilities management system includes a, number-of-unavailable-data calculation unit that calculates a number of unavailable meter-reading data in accordance with the meter-reading data obtained from the sensors having a communication function, an on-fault number-of-unavailable-data calculation unit that calculates the number of sensors having a communication function, placed in the power distribution system, and a fault determining unit that determines whether an open-circuit fault is occurring in the power distribution system, by comparing the number of placed sensors of the on-fault number-of-unavailable-data calculation unit, and the number of unavailable data calculated by the number-of-unavailable-data calculation unit.

The power distribution facilities management system further includes a system data storage unit in which the number of sensors with a communication function, existing in the power distribution system when the power distribution system is divided into an appropriate number of sections, is stored for each of the sections; wherein the on-fault number-of-unavailable-data calculation unit accesses the system data storage unit and calculates, on a section-by-section basis, the number of sensors having a communication function, and the fault determining unit determines whether the open-circuit fault in the power distribution system is occurring, by comparing for each section the number of, sensors having a communication function, and the section-specific number of unavailable data, calculated by the number-of-unavailable-data calculation unit.

The power distribution facilities management system further includes an unavailable data storage unit that stores, from the meter-reading data obtained from the sensors with a communication function via the communication system, a number of simultaneously unavailable data due to communication trouble; wherein, when the number of unavailable data calculated by the number-of-unavailable-data calculation unit is smaller than the number of simultaneously unavailable data due to communication trouble, retained in the unavailable data storage unit, the fault determining unit withholds determining whether an open-circuit fault is occurring in the power distribution system.

In addition, the fault determining unit sends an open-circuit fault determination result to a substation that supplies electric power to the distribution system.

Furthermore, each of the sensors with a communication function is placed at an electric power consumer house connected to the distribution system, acquires meter-reading data at predetermined intervals of time, and has a function for communicating wirelessly with at least one other sensor having a communication function and existing in a predetermined region.

Furthermore, the meter-reading data is at least one of electric power consumption, a voltage value, and a current value, detected at an electric power consumer house having one of the sensors provided with a communication function.

Furthermore, meter-reading data from each of the sensors with a communication function is collected in a meter-reading data collection unit, the meter-reading data collection unit being placed in plurality for one feeder, on the power distribution system, and having a function that uses wireless communication to collect at predetermined time intervals the meter-reading data measured by the metering devices placed within a predetermined region.

Furthermore, the system data storage unit retains data about a configuration of the distribution system, data about transformers installed on the distribution system, and data about interconnection between a transformer and metering devices each connecting thereto at a downstream section of the distribution system relative to the transformer.

Moreover, the fault determining unit is configured to: compare an unavailable state of the meter-reading data measured by each of the sensors with a communication function and an unavailable state of the meter-reading data that assumes an open circuit at a suitable location on the distribution system; and when a determination index that is a rate of the two unavailable states of the meter-reading data reaches a predetermined value, determine an open circuit to have occurred in the distribution system.

Besides, the fault determining unit is configured to: compare an unavailable state of the meter-reading data measured by each of the sensors with a communication function, and an unavailable state of the meter-reading data that assumes an open circuit in a line at a suitable location on the distribution system; and when a combination of those sensors with a communication function that are involved in the former unavailable state agrees at a predetermined rate with a combination of metering devices involved in the latter unavailable state under the assumed open circuit in the line, determine an open circuit to have occurred at the assumed location.

### Effects of the Invention

The present invention is effective for reducing the number of meters (sensors) placed in the power distribution system, and for saving equipment investments, as well as for detecting open-circuit faults very accurately.

### BRIEF DESCRIPTION OF THE DRAWINGS

FIG. 1 is a diagram showing a functional block configuration of the present invention that relates to detecting open circuits.

FIG. 2 is a diagram showing another functional block configuration of the present invention that relates to detecting open circuits.

FIG. 3 is a diagram showing an example of a power distribution system configuration including a high-voltage power distribution system and a low-voltage power distribution system.

FIG. 4 is a diagram that represents relationships between metering device identification codes and pole-mounted transformers.

FIG. 5 is a diagram showing an exemplary formation of a wireless communication route.

FIG. 6 is a time-serial representation of meter-reading data collected by a plurality of metering devices.

FIG. 7 is a diagram showing an example of a determination index computed by a fault determining unit.

FIG. 8 is an explanatory diagram that represents occurrences of open-circuit faults.

FIG. 9 is a diagram showing an example of meter-reading data acquisition and failure cases.

FIG. 10 is an explanatory diagram representing an example of correction term computation in a correction term computing unit.

FIG. 11 is a flowchart showing an open-circuit fault detection process.

FIG. 12 is a flowchart showing a fault determination process.

### MODES FOR CARRYING OUT THE INVENTION

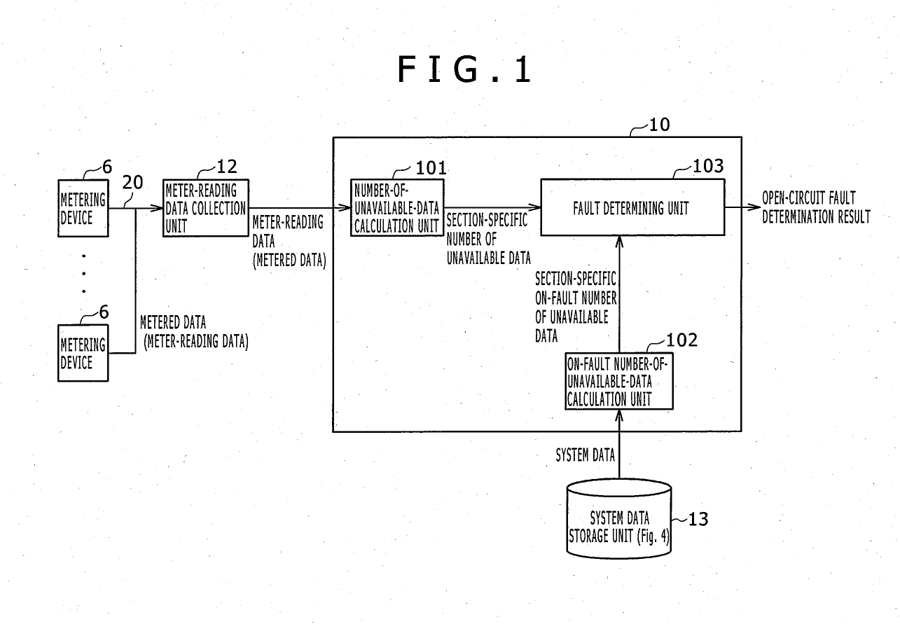

Hereunder, an open-circuit fault detecting method according to an embodiment of the present invention, and an electric power distribution facilities management system including the open-circuit fault detecting method will be described in detail referring to FIGS. 1 to 10. Common functional blocks in FIGS. 1-10 are each assigned the same reference number, and overlapped description of these functional blocks is omitted herein.

### First Embodiment

In the present invention, sensors each having a communication function, placed on a consumer, are used to detect open circuits on power distribution lines. Each of the sensors with a communication function measures and reads the amounts of water, gas, electricity, and other utilities consumed, and then transmits meter-reading data to a host via a power distribution line or a communication route such as a wireless communication channel.

Each sensor with a communication function generally operates on electric power supplied from the power distribution line. If there is an open circuit in power distribution line, therefore, the sensor with a communication function cannot transmit the meter-reading data, which then results in the meter-reading data being unavailable at the host. The present invention uses this, mechanism to detect the open circuit in the power distribution line.

First, a functional block configuration of the present invention that relates to the detection of open circuits is described below referring to FIG. 1. The sensors 6 with a communication function that are placed on the consumer (these sensors are hereinafter referred to as metering devices) are shown at a left side in FIG. 1. Meter-reading data on the water, gas, electricity, and other utilities consumption that has been measured by each sensor is collected via the communication route by a meter-reading data collection unit 12 placed in plurality at appropriate locations (e.g., on the power distribution system), and the thus-collected meter-reading data is sequentially read into an open circuit detecting section 10 at the host.

The meter-reading data collection unit 12 is placed in plurality for one feeder, on the power distribution system, and has a function that uses wireless communication to collect at predetermined time intervals the meter-reading data measured by the metering devices placed within a predetermined region.

The communication route 20 between the metering devices 6 and the meter-reading data collection unit 12 can be a power distribution line, a wireless communication channel, or the like, and the metering device 6 and the meter-reading data collection unit 12 communicate with each other and exchange the meter-reading data with each other. Thus the meter-reading data within the metering devices 6 is delivered in order from remote metering devices 6 to nearby remote metering devices 6.

Finally the meter-reading data within all metering devices 6 is sequentially aggregated into the meter-reading data collection unit 12 and read into the open circuit detecting section 10.

The communication between each metering device 6 and the meter-reading data collection unit 12 may employ whichever of two methods as follows: a parent device (the meter-reading data collection unit 12) periodically calls a child device (the metering device 6) to collect data; or the child device transmits data at predetermined periods.

An open-circuit fault detection computing function is provided in the open circuit detecting section 10 at the host, as shown in FIG. 1. The open circuit detecting section 10 includes a number-of-unavailable-data calculation unit 101 that calculates the number of metering devices 6 in which meter-reading data is unavailable (hereinafter, this number of metering devices 6 may also be referred to as the actual number of unavailable data). The open circuit detecting section 10 also includes an on-fault number-of-unavailable-data calculation unit 102 that calculates, with an assumption that an open-circuit fault will occur in a specific section on the power distribution system, the number of metering devices 6 in which meter-reading data is likely to become unavailable (hereinafter, this number of metering devices 6 may also be referred to as the case-based number of unavailable data). In addition, the open circuit detecting section 10 includes a fault determining unit 103 that determines whether an open-circuit fault has occurred in the distribution lines of the power distribution system, by using a rate of the actual number of unavailable data to the case-based number of unavailable data. In the determination by the fault determining unit 103, reference is made to system data within a system data storage unit 13.

The meaning of the actual number of unavailable data and that of the case-based number of unavailable data will be described in further detail later. Here, the meanings of both are briefly described. The actual number of unavailable data is an actual number of metering devices 6 in which unavailable meter-reading data has occurred, and the case-based number of unavailable data is a total number of placed metering devices 6 existing in the section when a point of occurrence of an open-circuit fault is assumed.

The open-circuit fault detection computing function of the present invention will be described in further detail hereunder. The power distribution system applying the open-circuit fault detection computing function, and the communication route used are first described by way of example below.

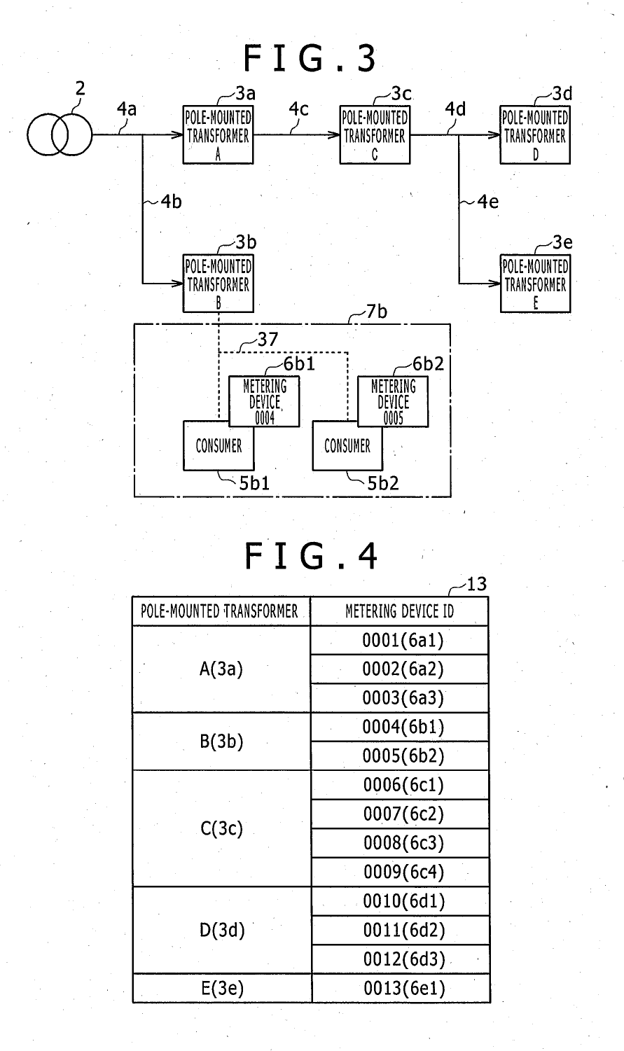

First, FIG. 3 shows an example of a power distribution system configuration including a high-voltage power distribution system and a low-voltage power distribution system. In the power distribution system that this example shows, a transformer 2 in a distribution substation is connected to pole-mounted transformers 3 in order via distribution lines 4. The elements present in this connection region constitute the high-voltage power distribution system. More specifically, the high-voltage power distribution system in FIG. 3 has a configuration with the elements connected in series in order of 2-4a-3a-4c-3-4d-3d, and the configuration is branched off at a section of 4a-4b-3b and a section of 4d-4e-3e.

In contrast to this, the pole-mounted transformers 3 convert a high voltage into a low voltage and form a low-voltage power distribution system between the transformers 3 themselves and a consumer 5. A configuration of the low-voltage power distribution system 7b connected to the pole-mounted transformer 3b is shown as an exemplary, configuration of the system connected between the pole-mounted transformers 3 and the consumer 5. Electric power consumer 5b1 and 5b2 are connected to the low-voltage power distribution system 7b via a low-voltage power distribution line 37, and metering devices 6b1 and 6b2 are placed on the power consumer 5b1 and 5b2, respectively.

Although not shown in FIG. 3, a low-voltage power distribution system is likewise configured for each of the pole-mounted transformers 3a, 3c, 3d, 3e as well, and electric power consumers 6 each provided with a metering device 6 are connected to these transformers. The metering devices 6 in this system configuration are each assigned an ID as a unique identification code for communication via the communication route 20. For example, the metering devices 6b1, 6b2 are defined as “0004”, “0005”, respectively. Similar identification codes, or IDs, are also assigned to the metering devices 6 connected to the other pole-mounted transformers 3a, 3c, 3d, 3e.

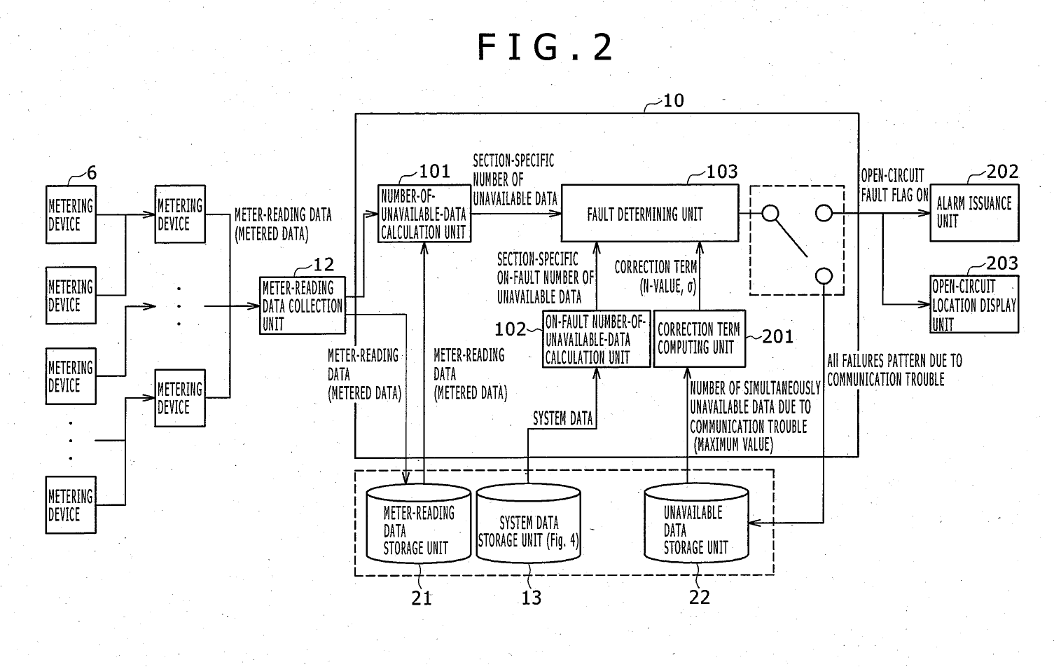

FIG. 4 is a tabular representation of association between the identification codes of metering devices 6 and the pole-mounted transformers that supply electric power to the metering devices. In FIG. 4, the pole-mounted transformers 3a-3e are shown at left and the metering devices connected to these transformers are shown with the respective identification codes, or IDs, at right. For pole-mounted transformer A (3a), for example; it can be seen that at the electric power consumer houses connected to the low-voltage power distribution system including the pole-mounted transformer, three metering devices, 6a1, 6a2, 6a3, that are defined as “0001”, “0002”, “0003”, are placed and these metering devices are electrically connected to the distribution system. Association similar to the above is also established between the other pole-mounted transformers C (3c), D (3d), E (3e) and respective metering devices 6, but this association would be easily understandable from the representation in FIG. 4, further detailed description of the association is omitted here. Data that has been bound together for representing these relations of connection between the pole-mounted transformers 3, and the metering devices 6 is stored in the system data storage unit 13 shown in FIGS. 1 and 2.

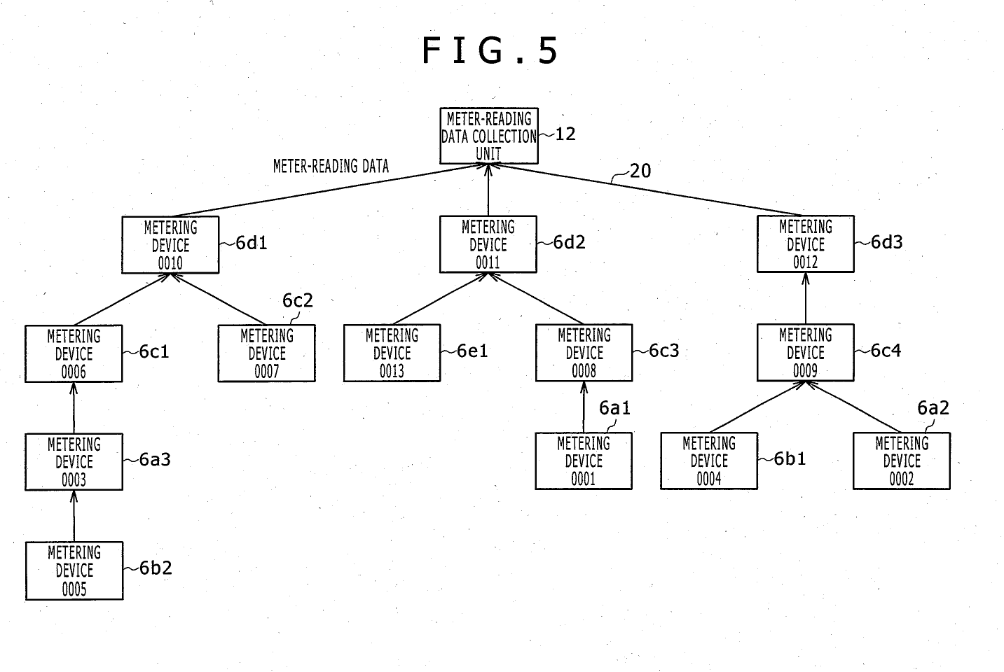

An exemplary relation of connection between the pole mounted transformers and metering devices at the power distribution system is shown in FIGS. 3 and 4, and an exemplary relation of connection between the metering devices and meter-reading data collection unit at the communication system is shown in FIG. 5.

FIG. 5 is an explanatory diagram showing an example of a meter-reading data communication route built between the metering devices having a wireless communication function. The metering devices 6 in this figure each have a wireless communication function, and between the metering devices located at relatively short distances, the metering devices 6 automatically generate the wireless communication route 20 for transmitting to the meter-reading data collection unit 12 the meter-reading data that each of the metering devices has measured. That is, the meter-reading data is exchanged between the metering devices by multi-hop communication.

In the example of FIG. 4, metering devices 6d1, 6d2, and 6d3 are arranged at first-stage positions in number of hops with respect to the meter-reading data collection unit 12. Additionally from the metering devices 6d1, 6d2, 6d3, respective metering devices 6c1 and 6c2, 6e1 and 6c3, and 6t4 are arranged at second-stage positions in the number of hops. Other metering devices also are likewise arranged at third-stage and lower-stage positions in the number of hops, but since the association between these metering devices would be easily understandable from the diagram of FIG. 5, detailed description of the metering devices is omitted here.

In this configuration, the metering devices at a lowermost end of the communication route transmit meter-reading data to the metering devices located at an immediately higher level of the communication route. The metering devices that have thus received the meter-reading data place their own meter-reading data upon the received data and transmit both sets of data together to the metering devises located at an even higher level. For example, the metering device 6b2 at one of fourth-stage hop positions transmits meter reading data to the metering device 6a3 located at one of third-stage hop positions, a level higher than that of the fourth-stage hop positions. The metering device 6a3 at one of the third-stage hop positions places the meter-reading data of the metering device's own upon the meter-reading data that the metering device 6a3 has received from the metering device 6b2 of the immediately lower level, and transmits both sets of data together to the metering device 6c1 located at one of the second-stage hop positions, an even higher level. Similarly, the metering device 6c1 at one of the second-stage hop positions places the meter-reading data of the metering device's own upon the meter-reading data that the metering device 6c1 has received from the metering devices 6b2, 6a3 of the immediately lower level, and transmits both sets of data together to the metering device 6d1 located at one of the first-stage hop positions, an even higher level.

Similarly the metering device 6d1 at one of the first-stage hop positions, the highest level of the communication route, transmits both the data of the metering device's own and the data that the metering device 6d1 has received from the metering devices of lower levels, to the meter-reading data collection unit 12. More specifically, in addition to the data that the metering device 6d1 has received from the metering devices 6b2, 6a3, 6c1 of lower levels, the metering device 6d1 transmits the meter-reading data that it has received from the metering device 6c2 on a separate route, to the meter-reading data collection unit 12.

While the metering devices 6d2, 6d3 at the other first stage positions also form a multi-hop communication route in accordance with the same concept as that described above, detailed description of the data exchanges between the metering devices 6d2, 6d3 and other metering devices is omitted here since the association between these metering devices would be easily understandable from the diagram of FIG. 5.

In this way, the wireless communication route for the metering devices in the present invention has a tree-like structure and can use multi-hop communication to collect the meter-reading data within the distribution system by transmitting meter-reading data in order from remote metering devices to the meter-reading data collection unit 12.

An example of a power distribution system configuration has been described above per FIG. 3, and an example of a communication route configuration per FIG. 5. As is evident from these examples, the distribution system configuration and the communication route configuration are established separately from one another and the communication route is not formed along the distribution system configuration. When the distribution system configuration and the communication route configuration are placed in operation, both are subject to change as appropriate, to suit a particular situation. For example, a power-feeding route for the pole-mounted transformers may be changed for a reason such as distribution system switching, or a connection destination may be changed to a metering device of a higher level in quest of a frequency channel of a better receiving environment on the communication route.

However, even when the distribution system configuration and the communication route configuration are established separately and undergo changes as appropriate, the layout relationship between pole-mounted transformers and metering devices, shown in FIG. 4, remains fixed, so that the relationship between the distribution system configuration and the communication route configuration can be understood by associating both configurations as per the table of FIG. 4.

The transmission and reception of meter-reading data are carried out at fixed periods of time, and are repeatedly performed in line with predetermined metering cycles of time. Thus, the meter-reading data detected at the same time of day at various locations in the distribution system will be collected into the meter-reading data collection unit 12.

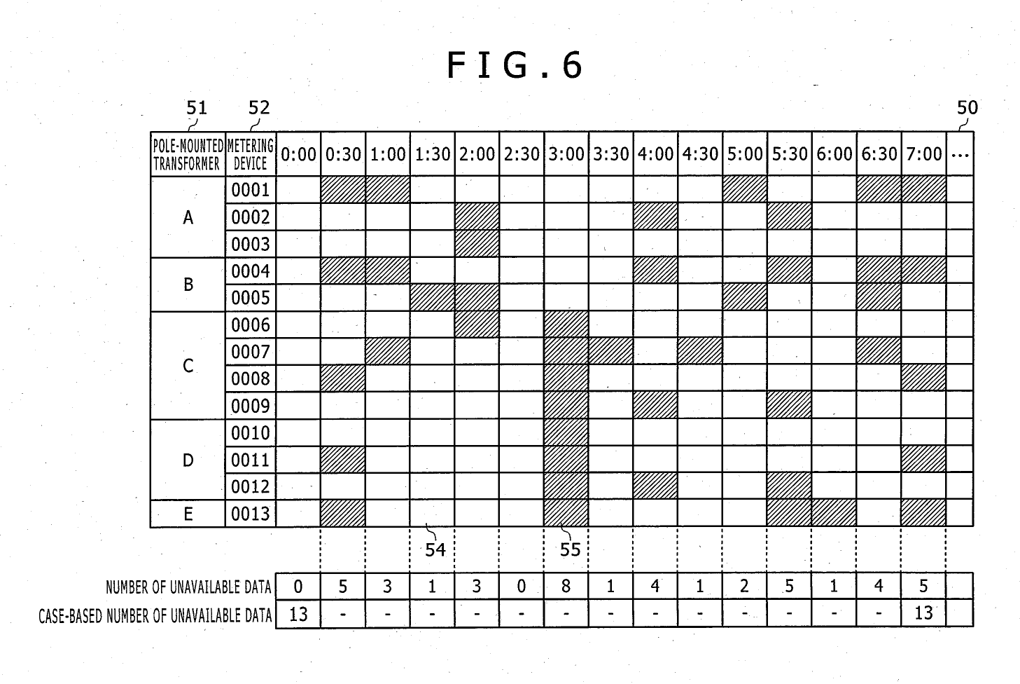

FIG. 6 is a time-serial representation of the meter-reading data simultaneously collected from a plurality of metering devices at each time.

An example in which the meter-reading data that has been obtained every 30 minutes is listed in FIG. 6 to represent acquisition/unavailability of the meter-reading data. Shaded sections denote the unavailability of the data, and blank sections denote the reception of a set of meter-reading data. The unavailable data is recognized by and recorded in the meter-reading data collection unit 12 as real-time state data for each identification code (ID) of the pole-mounted transformers and for each identification code (ID) of the metering devices powered from the transformer.

Table 50 shown in FIG. 6 denotes, on a vertical axis, a list 51 of the pole-mounted transformers installed in the distribution system, and a list 52 of the metering devices placed at the power consumer houses connected to the pole mounted transformers. The acquisition and unavailable states of meter-reading data at each metering period of the metering devices are represented on a horizontal axis of the table 50 shown in FIG. 6. This metering period of the metering devices is 2 minutes, for example. During actual operation, however, the metering period may be 1 minute, 3 minutes, 5 minutes, 10 minutes, 15 minutes, 20 minutes, or other. For sake of convenience in description, the unavailable state from 0:00 to 7:00 on a certain day is represented in units of 30 minutes in tabular form in FIG. 6.

A blank box (e.g., 54) in the table means that the meter-reading data collection, unit 12 has acquired the meter-reading data measured by the metering device. A shaded box (e.g., 55), on the other hand, means that the meter-reading data collection unit 12 has failed to acquire the meter-reading data measured by the metering device (i.e., the data is unavailable).

Examples are described below referring to the communication route shown in FIG. 5. When attention is focused upon the metering device 6a2 “0002” in the table 50 of FIG. 6, the meter-reading data that was measured at the time of 0:00 and 1:00 is transmitted to the meter-reading data collection unit 12 through the metering devices 6C4 “0009” and 6d3 “0012”, which means that the open circuit, detecting section 10 has acquired the meter-reading data.

The meter-reading data that the metering device 6a2 “0002” measured at the time of 2:00 and 4:00, on the other hand, fails to reach the meter-reading data collection unit 12, and the meter-reading data is unavailable in the open circuit detecting section 10. Meter-reading data may also become unavailable in a plurality of metering devices in the same time zone (simultaneously unavailable).

During actual operation, however, the number-of-unavailable-data calculation unit 101 in the open circuit detecting section 10 calculates a number of unavailable meter-reading data, in line with the metering period. That is, in the present embodiment, number of unavailable meter reading data coming in at intervals of 2 minutes is computed each time the data is received. The acquisition and unavailable states of the meter-reading data measured by various metering devices can thus be confirmed.

In the present invention, the table of FIG. 6 that represents the acquisition and unavailable states of the meter-reading data measured by different metering devices may be output to, for example, a display of a terminal PC or cell phone or large-size monitor that connects with the distribution facilities management system.

The unavailability here means a state in which the data that should be obtained at predetermined time is not collected. Causes of the collecting failure exist at both of the distribution side and the communication side. Among the causes relating to the distribution side is the open circuit in the distribution line. A large portion of the metering devices 6 operate on the power supplied from the distribution system, and these devices therefore do not have other power supplies such as storage cells. For this reason, an open circuit in the distribution system interrupts the supply of power to the metering devices 6, hence rendering these devices unable to transmit data, which means that the data that should be obtained at the predetermined time is not collected into the meter-reading data collection unit 12.

If any communication trouble occurs as a cause relating to the communication side, the data that should be obtained at the predetermined time will not be collected because of receiving trouble.

States to be defined as the unavailable state preferably include a state in which the amount of electric power detection data is zero. For example, assuming that a metering device that measures electric power consumption has any other power supply such as cells, the metering device can communicate even if there is an open circuit in, the distribution system. In this case, power detection data that assigned as zero can be obtained. Accordingly, this case can also be managed.

In the present invention, the association between transformers and metering devices, shown in FIG. 4, is utilized and the detection of distribution open circuit is performed in the following manner with respect to the unavailable data detected at fixed periods.

First, the number-of-unavailable-data calculation unit 101 in FIG. 1 recognizes the number of unavailable data at measuring time periods. If this state is described using the example of FIG. 6 that shows the data obtained at 30-minute periods, then as shown in a field of FIG. 6 that represents a number of unavailable data, the number of unavailable data at the measuring time of 0:00 becomes “0”, the number at 0:30 becomes “5”, and subsequent collection results at 30-minute periods become “3”, “1”, “3”, “0”, “8”, “1”, “4”, “1”, “2”, “5”, “1”, “4”, “5”.

Next, the on-fault number-of-unavailable-data calculation unit 102 reads in predetermined system data from the system data storage unit 13 and similarly calculates the case-based number of unavailable data in each of predetermined sections. As described earlier herein, the relationship in FIG. 4 is stored within the system data storage unit 13. For example, an entire region of the distribution system in FIG. 3 is assumed here as the predetermined sections. That is to say, there is estimated an open circuit in the distribution line 4a directly under the substation 2. The case-based number of unavailable data is the total number of metering devices 6 placed in the particular section. The case-based number of unavailable data is a total of 13, three connected to pole-mounted transformer A, two to pole-mounted transformer B, four to pole-mounted transformer C, three to pole-mounted transformer D, and one to pole-mounted transformer E.

The present invention assumes that when a substantial number of metering devices in the section are unavailable, the open circuit is most likely to have been occurred. Under the state of 3:00 in FIG. 6, for example, data is unavailable in 8 of the 13 metering devices and the occurrence of the open circuit is suspected.

For these reasons, the fault determining unit 103 in FIG. 1 sequentially computes a determination index ρ for each predetermined section and each time at the predetermined time, the determination index ρ taking the actual number of unavailable data as a numerator and the case-based number of unavailable data as a denominator. If the determination index ρ exceeds a threshold value, the open circuit is determined to have occurred.

At this time, a location of the open circuit on the distribution system can also be identified by checking with the determination index values for the sections. Since the determination index ρ ranges from 0.0 to 1.0, any threshold value can be set that falls within a range of 0.0<p≦1.0.

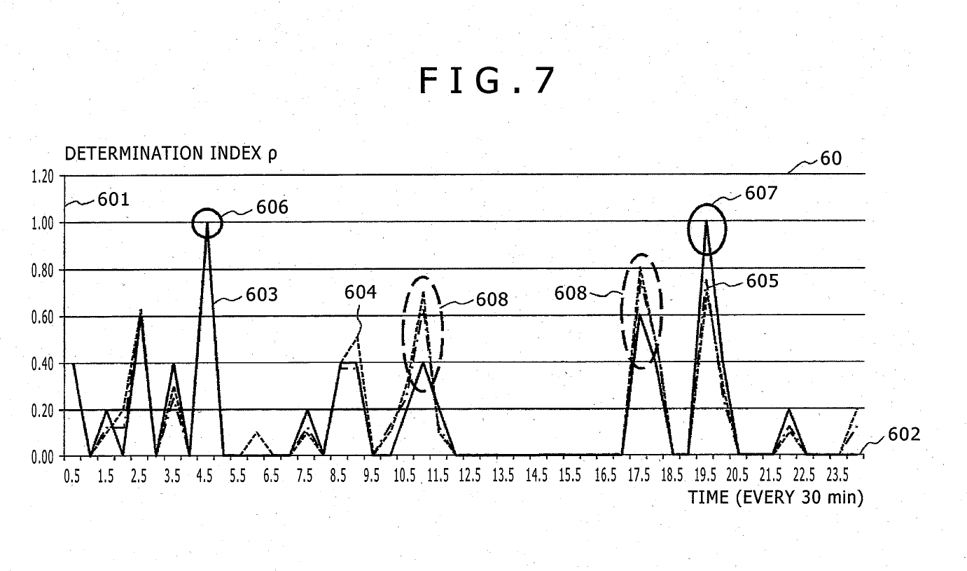

FIG. 7 is an explanatory diagram showing an example of a determination index computed by the fault determining unit 103. FIG. 7 is a line chart 60 that shows time changes in the determination index ρ that correspond to the metering period. A vertical axis 601 denotes the determination index ρ, a horizontal axis 602 denotes time, and the determination index ρ is expressed in units of 30 minutes. Polygonal lines 603, 604, 605 shown on the graph 60 denote the respective values of the determination index ρ for each of the predetermined sections, and p is calculated using expression (1).

(Numerical expression 1)

ρ=LER/LAC (1)

where LER, the numerator, is the actual number of unavailable data and LAC, the denominator, is the case-based number of unavailable data. Basically a relation of LAC≧LER exists and as can be seen from expression (1), the determination index ρ can take any value falling within a range shown in expression (2).

(Numerical expression 2)

0.0≦ρ≦1.0 (2)

In an example of the determination according to the present invention, as can be seen from expression (1), if the determination index ρ is smaller than 1.0, an open-circuit fault is determined not to be occurring, and if the determination index ρ is 1.0, then LER=LAC, in which case an open-circuit fault is determined to be occurring. Whether the fault is occurring is determined on the basis of these criteria. In a case of the graph 60, a state of determination index values 606 and 607 circle-marked with a solid line atop indicates that an open-circuit fault is occurring.

In states of determination index values 608 circle-marked with a dotted line atop, determination index values 604 and 605 lie in a 0.6 to 0.8 range and are not 1.0. Thus, this state is determined not to be an open-circuit fault, but that a plurality of unavailable data have simultaneously occurred due to communication trouble.

A criterion for fault determination based upon the determination index ρ can be set to lie in any range as in expression (3), wherein ρACC is a lower-limit value of the fault determination criterion.

(Numerical expression 3)

ρACC≦ρ≦1.0 (3)

In another example of the determination according to the present invention, although the determination index is not 1.0, when the index is a large value, open circuit at a downstream side is considered to be most likely. In other words, when the determination index ρ is calculated assuming the open circuit in the distribution line 4a in FIG. 3, if as at the time of 3:00 in FIG. 6, p=0.6 (8/13), then this state is most likely to indicate, albeit not an open-circuit fault in the assumed section, that the line is disconnected at the downstream side. Under the state of interest, the present invention enables the section of the open circuit to be located by continuing the determination process after changing the assumed section to the downstream side.

As described above, open-circuit faults in the power distribution system can be detected by comparing, as in expression (1), the actual number of unavailable meter-reading data and the case-based number of unavailable data in each of the predetermined sections.

### Second Embodiment

Next, a functional block configuration of an open-circuit fault detecting method provided in the electric power distribution facilities management system, another embodiment of the present invention, is described below referring to FIG. 2.

FIG. 2 is a block diagram showing an outline of the open-circuit fault detecting method according to the present embodiment. As shown in FIG. 2, this open-circuit fault detecting method is included as the open circuit detecting section 10 in the power distribution facilities management system.

The open circuit detecting section 10 in this case, as with that of the embodiment in FIG. 1, includes a number-of-unavailable-data calculation unit 101 that computes an actual number of unavailable data, an on-fault number-of-unavailable-data calculation unit 102 that computes a case-based number of unavailable data, and a fault determining unit 103 that determines whether an open circuit exists in a distribution line that forms part of a power distribution system. The open circuit detecting section 10 also includes a correction term computing unit 201 that computes a threshold value for preventing an actual unavailable data due to communication trouble from being determined to be a value indicating the occurrence of an open-circuit fault.

In addition to the system data storage unit 13 as an external database in FIG. 1, the open circuit detecting section 10 in this case further includes other external databases, namely a meter-reading data storage unit 21 and an unavailable data storage unit 22, and the open circuit detecting section 10 works with these storage units to transmit and receive necessary data. The meter-reading data storage unit 21, the system data storage unit 13, and the unavailable data storage unit 22 are constituted by a hard disk drive (HDD) that forms part of a server or the like, an auxiliary storage device such as a flash memory, a main storage device such as a main memory, and other recording media.

The meter-reading data storage unit 21, one of the external databases, stores meter-reading data that the meter-reading data collection unit 12 has collected. In addition to a configuration of the power distribution system, the system data storage unit 13 stores equipment data about distribution lines, pole-mounted transformers, switchgears, and other pieces of distribution equipment installed in the distribution system. The equipment data includes specifications, IDs, and other management numbers of the distribution equipment. Other elements of the equipment data are, for example, installation locations for the equipment, the number of years passed after installation of the equipment, and the number of years of operation of the equipment. The unavailable data storage unit 22 stores an unavailable state of past meter-reading data relating to predetermined metering devices 6.

The unavailable state stored into the unavailable data storage unit 22 refers to the actual number of unavailable data and to a combination and number of metering devices (simultaneous acquisition failure patterns) in which necessary data has become unavailable at the same time (simultaneous acquisition failures). In addition, causes of data acquisition failures are stored in two separate categories: failures due to a fault such as open circuit, and failures due to communication trouble.

The correction term computing unit 201 reads in, among all past simultaneous acquisition failure patterns stored into the unavailable data storage unit 22, only a simultaneous acquisition failure pattern maximized in the actual number of unavailable data due to communication trouble, and sets a correction term σ for the distribution system.

The correction term computing unit 201 accesses the unavailable data storage unit 22 and recognizes that the maximum number of simultaneously unavailable data caused by communication trouble in the past is eight (in other words, eight metering devices). In this case, the correction term computing unit 201 determines that although caused by communication trouble, the simultaneous unavailable data in up to eight metering devices will frequently occur, and sets the correction term σ that corrects a determination index ρ. This setting prevents the fault determining unit 103 from determining the state of simultaneous acquisition failures in not more than eight metering devices, to be due to open circuit.

If the open circuit detecting section 10 determines open circuit to have occurred, this result is output to an alarm issuance unit 202 and an open-circuit location display unit 203. The alarm issuance unit 202 is disposed in, for example, a consumer service operations office with resident service personnel, and upon receiving a determination result message “Open-circuit fault occurring” from the open circuit detecting section 10 in the distribution facilities management system, the alarm issuance unit 202 can issue an alarm and audibly inform the open-circuit fault to the service personnel. The open-circuit location display unit 203 is also disposed in the consumer service operations office or the like, and can visually inform the open-circuit fault to the service personnel. The open-circuit location display unit 203 is for example, a display of a terminal PC or cell phone or large-size monitor that connects with the distribution facilities management system.

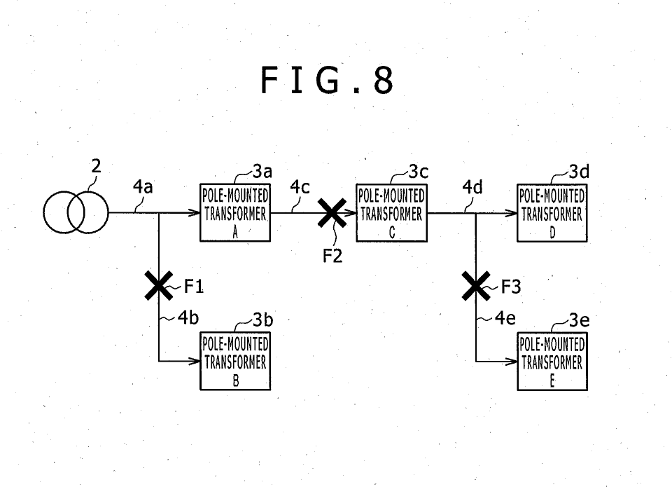

FIG. 8 is an explanatory diagram that represents occurrences of open-circuit faults. Referring to FIG. 8, which shows an example of the same distribution system as that of FIG. 3, the distribution system includes a transformer 2 of a distribution substation, pole-mounted transformers 3a to 3e, and distribution lines 4a to 4e interconnecting the pole-mounted transformers 3a to 3e. Symbols X shown as F1, F2, F3 on various sections of the distribution system in FIG. 8 signify assumed locations of occurrence of open-circuit faults. While these open-circuit faults may occur separately or simultaneously during actual operation, these faults are described in the present embodiment as having occurred separately.

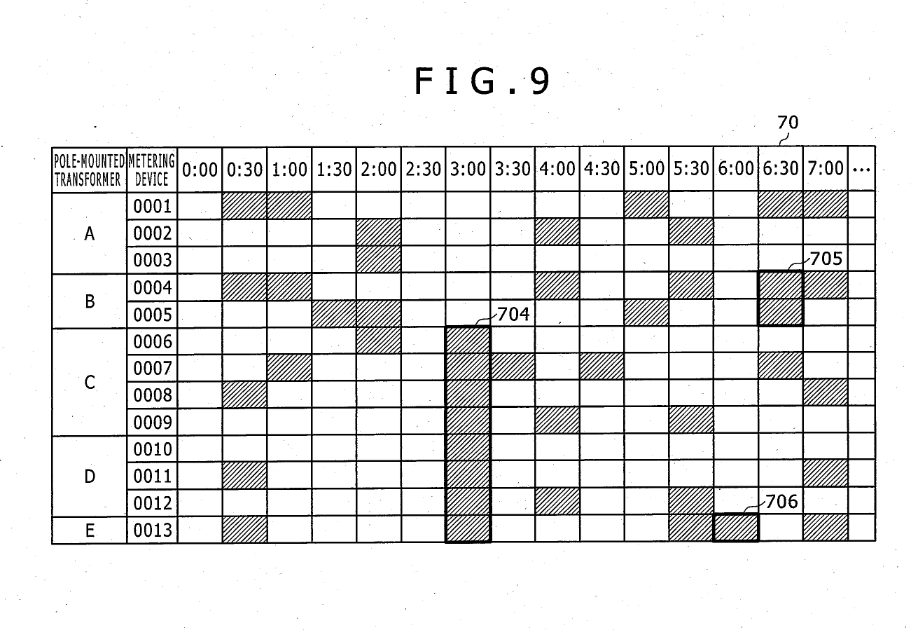

Table 70 of FIG. 9 is a diagram representing an example of the same acquisition/unavailable states of meter-reading data as those shown in FIG. 6. Unavailable data regions 705, 704, 706 each enclosed in a black border in FIG. 9 correspond to the open-circuit locations F1, F2, F3 in FIG. 8.

Suppose, for example, that an open-circuit fault occurred as a first open-circuit fault case in a time zone of 3:00-3:30 at the location F2 on a section of a distribution line 4C lying between pole-mounted transformers A (3a) and C (3c) in FIG. 8. In this, case, electricity does not flow into pole-mounted transformers C (3c), D (3d), E (3e) located downstream relative to the open-circuit location F2 in the distribution system. This means that the metering devices connected to the three pole-mounted transformers, 3c, 3d, 3e, do not operate and thus that meter-reading data from these metering devices 6 cannot be acquired.

Therefore, the acquisition of meter-reading data in the time zone of 3:00 in Table 70 of FIG. 9 simultaneously fails in the metering devices 0006, 0007, 0008, 0009 connected to pole-mounted transformer C (3c), the metering devices 0010, 0011, 0012 connected to pole-mounted transformer D (3d), and the metering device 0013 connected to pole-mounted transformer C (3c). The unavailable data region 704 is a representation of these simultaneously unavailable data.

In other words, if a plurality of meter-reading data simultaneously become unavailable in a time zone as described above, it can be determined that an open-circuit fault has occurred. In addition, as shown in Table 70, a location of the open circuit can be identified from factors such as simultaneous unavailable data pattern 704 of the metering devices, according to the metering devices and the pole mounted transformer to which the metering devices are connected.

In the present example, data is not unavailable in the metering devices 6 connected between pole-mounted transformers A (3a) and B (3b), and data is unavailable in all of the metering devices 6 connected between pole-mounted transformers C (3c), D (3d), E (3e). These results indicate that electricity is flowing through the distribution lines 4a, 4b and that electricity is not flowing through the distribution lines 4c, 4d, 4e. The location of the open circuit can therefore be identified as F2.

Next, suppose that an open-circuit fault occurred as a second open-circuit fault case in a time zone of 6:00-6:30 at the location F1 on the distribution line 4b lying upstream relative to pole-mounted transformer B (3b). In this case, electricity does not flow into pole-mounted transformer B (3b) located downstream relative to the open-circuit location F1 in the distribution system. This means that the metering devices 0004 and 0005 connected to pole-mounted transformer B (3b) do not operate and thus that meter-reading data from these metering devices cannot be acquired. Therefore, the acquisition of meter-reading data in the time zone of 6:00-6:30 in Table 70 of FIG. 9 simultaneously fails in the metering devices 0004 and 0005. The region 706 is a representation of these simultaneously unavailable data.

Similarly, suppose that an open-circuit fault occurred as a third open-circuit fault case in the time zone of 6:00-6:30 at the location F3 on the distribution line 4e. In this case, since electricity does not flow into pole-mounted transformer E (3e) located downstream relative to the open-circuit location F3, electricity does not flow into the metering device 0013 connected to pole-mounted transformer E (3e) and this metering device fails to operate. That is to say, meter-reading data from the metering device 0013 cannot be acquired. The acquisition of meter-reading data in the time zone of 6:00-6:30 in Table 70 of FIG. 9, therefore, fails in the metering device 0013 and this unavailable data appears as the unavailable data region 706.

As set forth above, an open-circuit fault can be determined from the interconnection relationship between a pole-mounted transformer and metering devices connected to the pole-mounted transformer, and from certain of the meter-reading data in the metering devices being in an unavailable state, and the location of the open circuit can be identified as a result.

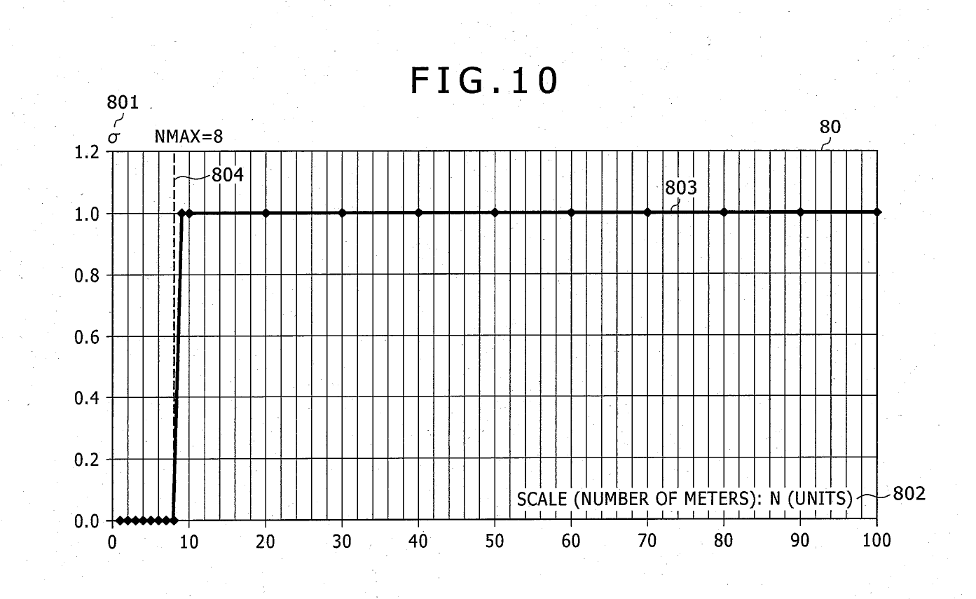

FIG. 10 is an explanatory diagram representing an example of correction term computation in the correction term computing unit 201. FIG. 10 is a graph representing a relation between the correction term σ taken on a vertical axis 801, and a number of simultaneously unavailable data (open-circuit fault scale) N taken on a horizontal axis 802. In the present example, the correction term σ is defined as a step function 803 in expression (4).

(Numerical expression 4)

σ=0 (N≦8)

σ=1 (N>8) (4)

A threshold value 804 of the step function is described below. The present example employs a maximum number of simultaneously unavailable metering device (maximum number of simultaneously unavailable data) due to communication trouble. In the distribution system for which the present example is intended, the maximum number of the simultaneously unavailable data, NMAX, is 8, which means that an unavailable meter-reading data due to communication trouble is likely to occur in up to eight metering devices at the same time. Therefore, the determination index in expression (1) is corrected as follows using the correction term σ to prevent the state of not more than eight simultaneous acquisition failures due to communication trouble from being erroneously determined to be an open-circuit fault:

(Numerical expression 5)

ρ=LER/LAC×σ(5)

From expressions (4) and (5), the correction term a equals 0 for not more than eight simultaneous acquisition failures.

This means that the correction term σ is corrected so that even if simultaneous acquisition failures occur in not more than eight metering devices, this state will not be determined to be an open-circuit fault. Correcting the correction term σ in this manner will prevent an event of frequent unavailable data due to communication trouble or the like, from being determined to be an open-circuit fault.

The open-circuit fault scale N, adopted as the threshold value in the present example, can be optionally set. That is, any value can be assigned on the basis of the number of simultaneously unavailable metering devices located in the distribution system or feeder of interest. Alternatively, any value may be assigned, irrespective of the number of the simultaneously unavailable metering devices.

If it is possible to reduce a likelihood that the unavailable state of meter-reading data due to communication trouble may be determined to be an open-circuit fault, the step function of the correction term σ can be any value other than 0 and 1, or alternatively can be replaced by a linear function, a quadratic function, a high-dimensional function, an exponential function, a logarithmic function, or the like.

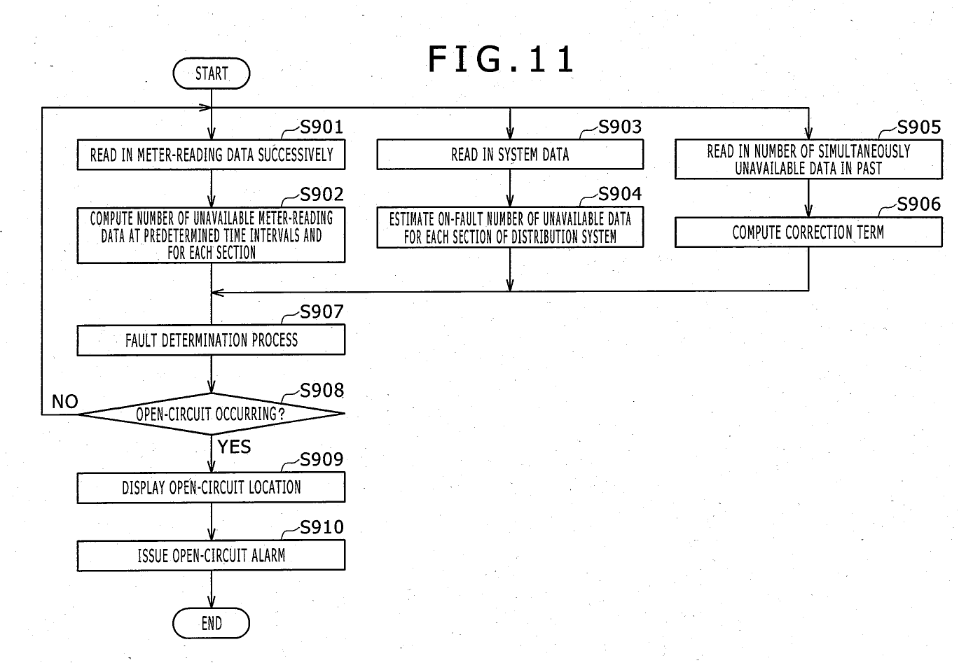

Next, open-circuit fault detection by the open circuit detecting section 10 is described below referring to FIG. 11.

FIG. 11 is a flowchart showing the open-circuit fault detection process provided in the power distribution facilities management system.

The open-circuit fault detection process is started upon input of the meter-reading data from the metering devices to the open circuit detecting section 10, and is repeatedly performed in line with the metering period or communication period of the metering devices. The open-circuit fault detection process is performed to detect a open circuit in the distribution lines which form part of the distribution system, and identify a location of the open circuit.

Meter-reading data that the meter-reading data collection unit 12 has collected from each metering device 6 is loaded and acquired in first step S901 of the open-circuit fault detection process shown in FIG. 11.

In step S902 following the above acquisition step, the number-of-unavailable-data calculation unit 101 computes the actual number of unavailable meter-reading data, except for the metering readings data that was acquired in step S901.

During this computation, the count of data acquisition failures is computed for each predetermined section into which the distribution system has been divided at each pole-mounted transformer. The actual number of unavailable data is computed by, for example, counting the number of unavailable data flag signals (fDATALACK=1) that are transmitted to indicate a lack of necessary data.

In step S903, system data is read in and acquired from the system data storage unit 13, one of the databases. The system data is data relating to the distribution system and the constituent elements of the distribution system. For example, the system data include the configuration of the distribution system, the installation locations for the equipment constituting the distribution system, the number of years passed after installation of the equipment, and the specifications and operation parameters of the equipment. More particularly, the system data here includes the bound data shown in Table 13 of FIG. 4 to represent the relationships between pole-mounted transformers and the metering devices connected to the pole-mounted transformers, and the data relating to the predetermined sections into which the distribution lines 4a-4e of the distribution system, shown in FIG. 3, has been divided according to the particular distance between pole-mounted transformers.

In step S904 following the above acquisition step, the on-fault number-of-unavailable-data calculation unit 102 computes the number of unavailable data in the particular predetermined section of the distribution system or in a previously assumed case of an open-circuit fault.

In step S905, the correction term computing unit 201 reads in and acquires the maximum number of simultaneously unavailable data in the past, NMAX, from the unavailable data storage unit 22, one of the databases.

In step S906 following the above acquisition step, the correction term computing unit 201 defines the correction term σ on the basis of the maximum number of simultaneously unavailable data, NMAX, that was loaded and acquired in step S905 (see FIG. 10 for further details of the definition).

In step S907 following the above series of data input and processing steps, the fault determining unit 103 computes the determination index ρ in accordance with expression (5). This computation uses the actual number of unavailable data, LER, that was computed in step S902, the case-based number of unavailable data LAC, that was computed in step S904, and the correction term σ that was computed in step S906.

In step S908, the fault determining unit 103 determines whether the computed correction term σ satisfies an open-circuit fault determination criterion defined in expression (6) or (7).

(Numerical expression 6)

ρ=1.0 (6)

(Numerical expression 7)

ρACC≦ρ≦1.0 (7)

Of these expressions, expression (6) derived from the relationship between LER that is the actual number of unavailable data, and LAC that is the case-based number of unavailable data, becomes expression (8), which means that an open-circuit fault has occurred.

(Numerical expression 8)

LER=LAC (8)

The above assumes that either expression (6) or (7) is set as the open-circuit fault determination criterion.

Any value based upon expression (9) can be assigned to ρACC.

(Numerical expression 9)

0.0<ρACC<1.0 (9)

If it is determined in step S908 that expression (6) or (7) is satisfied and that an open-circuit fault has occurred, the open-circuit location display unit 203 displays a location of the open circuit in step S909 and then an alarm is issued in step S910 to notify that the open-circuit fault occurred.

Conversely if it is determined in step S908 that, expression (6) or (7) is not satisfied and that an open-circuit fault is not occurring, process control is returned to the first step of the open-circuit fault detection process and this process is resumed from steps S901, S903, and S905.

During the open-circuit fault detection process in the above-described open circuit detecting section 10, alarm issuance unit 202, and open-circuit location display unit 203, whether an open-circuit fault has occurred is determined in accordance with certain of the meter-reading data being in an unavailable state, as described above. Accordingly, the metering devices with a communication function, placed at the electric power consumer houses, can be used to detect the open circuit.

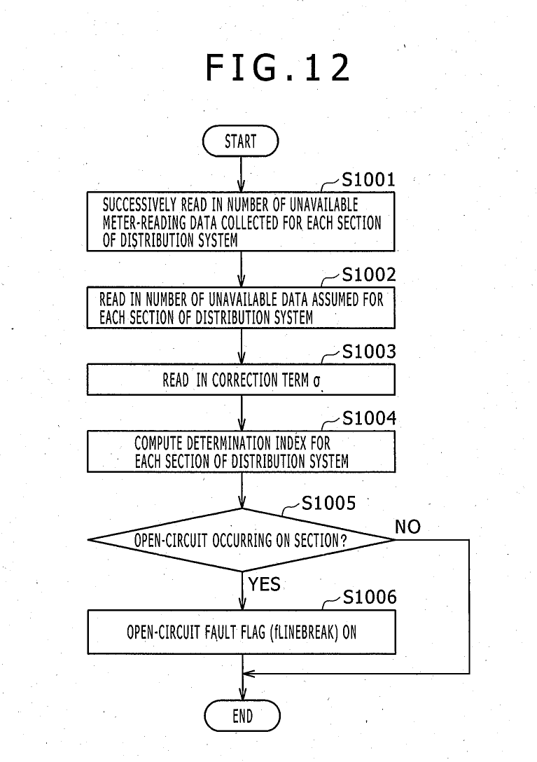

Next, the open-circuit fault determination process in the fault determining unit 103 is described below referring to FIG. 12. FIG. 12 is a flowchart showing the fault determination process in the open-circuit fault detecting method.

The open-circuit fault determination process is started upon input of the computed section-specific actual number of unavailable data from the number-of-unavailable-data calculation unit 101 to the fault determining unit 103, and is repeatedly performed in line with the metering period or communication period of the metering devices. The fault determination process is performed to detect an open circuit in the distribution lines which form part of the distribution system.

In step S1001, the actual number of unavailable data, LER, that the number-of-unavailable-data calculation unit 101 has computed is read in and acquired.

In step S1002, the case-based number of unavailable data, LAC, that the on-fault number-of-unavailable-data calculation unit 102 has computed is read in and acquired.

In step S1003, the correction term σ that the correction term computing unit 201 has computed is read in and acquired.

In step S1004, the determination index ρ for the particular predetermined section is computed as per expression (5).

In step S1005, it is determined whether the determination index ρ that was computed in step S1004 meets the fault determination criterion represented by expression (6) or (7).

If it is determined in step S1005 that the fault determination criterion in expression (6) or (7) is met and that an open-circuit fault has occurred, an open-circuit fault flag fLINEBREAK is set to ON (fLINEBREAK=1). The open-circuit fault flag ON signal is output to the alarm issuance unit 202 and the open-circuit location display unit 203, thereby to complete the fault determination process.

If it is determined in step S1005 that the fault determination criterion in expression (6) or (7) is not met and that an open-circuit fault is not occurring, the open-circuit fault flag fLINEBREAK is set to OFF (fLINEBREAK=0), with which the fault determination process terminates.

The above-detailed power distribution facilities management system of the present invention has much in common with a metering system that measures the amounts of electricity, gas, supply water, and/or other utilities consumed, from the meter-reading data within the sensors placed with a communication function at consumers. For this reason, for example an electrical energy consumption metering system that measures the consumption of electricity will be installed and used, along with the power distribution facilities management system, at a customer service operations office of the power company.

However, since open-circuit fault data will be actually used in the substation, not the customer service operations office, open-circuit fault detection data will be transferred to the substation and used thereat. In consideration of this, the alarm issuance unit 202 and open-circuit location display unit 203 shown in FIG. 2 are preferably disposed inside the substation.

### DESCRIPTION OF REFERENCE NUMBERS

10: Internal-open-circuit detecting section (minimum configuration) of power distribution facilities management system, 6: Metering device, 12: Meter-reading data collection unit, 13: System data storage unit, 20: Internal-open-circuit detecting section of power distribution facilities management system, 21: Meter-reading data (meter readings) storage unit, 22: Unavailable data storage unit, 101: Number-of-unavailable-data calculation unit, 102: On-fault number-of-unavailable-data calculation unit, 103: Fault determining unit, 201: Correction term computing unit, 202: Alarm issuance unit, 203: Open-circuit location display unit

1. A method for detecting an open-circuit fault in an electric power distribution system, comprising:
placing sensors, each provided with a communication function, on a consumer connected to the power distribution system;
obtaining, via a communication system, meter-reading data detected by each of the sensors provided with a communication function; and
detecting an open circuit in the power distribution system in accordance with an unavailable state of the meter-reading data.

2. The method for detecting an open-circuit fault in an electric power distribution system according to claim 1, wherein:
the number of those sensors with a communication function each indicating unavailability of meter-reading data is compared with the number of those sensors with communication function placed in the power distribution system, thereby determining whether an open circuit has occurred in the electric power distribution system.

3. The method for detecting an open-circuit fault in an electric power distribution system according to claim 2, wherein:
the power distribution system is divided into an appropriate number of sections;
the number of those sensors with a communication function each reporting unavailability of meter-reading data in a corresponding section is compared with the number of those sensors with a communication function placed in the corresponding section, thereby determining whether an open circuit has occurred in the electric power distribution system.

4. The method for detecting an open-circuit fault in an electric power distribution system according to claim 2, wherein:
a number of simultaneously unavailable data due to communication trouble is retrieved and retained from a past history; and
the detection of an open circuit in the power distribution system is performed when the number of those sensors with a communication function reporting the unavailability of meter-reading data is greater than the number of simultaneously unavailable data due to communication trouble.

5. The method for detecting an open-circuit fault in an electric power distribution system according to claim 3, wherein:
the sections of the power distribution system are changed in order, thereby successively determining for each sections whether an open circuit has occurred in the electric power distribution system.

6. The method for detecting an open-circuit fault in an electric power distribution system according to claim 1, wherein:
the unavailable state of the meter-reading data includes a state in which the amount of meter-reading data detected by at least one of the sensors having a communication function is zero.

7. An electric power distribution facilities management system that obtains meter-reading data of the sensors with a communication function, via a communication system, from a power distribution system to which consumers each including a sensor with a communication function are connected, the power distribution facilities management system comprising:
a number-of-unavailable-data calculation unit that calculates a number of unavailable meter-reading data in accordance with the meter-reading data obtained from the sensors with a communication function;
an on-fault number-of-unavailable-data calculation unit that calculates the number of sensors with a communication function placed in the power distribution system; and
a fault determining unit that determines whether an open-circuit fault is occurring in the power distribution system, by comparing the number of sensors calculated by the on-fault number-of-unavailable-data calculation unit and the number of unavailable data calculated by the number-of-unavailable-data calculation unit.

8. The power distribution facilities management system according to claim 7, further comprising:
a system data storage unit in which the number of sensors with a communication function, existing in the power distribution system when the power distribution system is divided into an appropriate number of sections, is stored for each of the sections, wherein:
the on-fault number-of-unavailable-data calculation unit accesses the system data storage unit and calculates on a section-by-section basis the number of sensors with a communication function; and
the fault determining unit determines whether the open-circuit fault in the power distribution system is occurring, by comparing for each section the number of sensors with a communication function and the number of unavailable data in the section calculated by the number-of-unavailable-data calculation unit.

9. The power distribution facilities management system according to claim 7, further comprising:
a meter-reading data storage unit that stores a number of simultaneously unavailable data due to communication trouble, via the communication system, from the meter-reading data obtained from each of the sensors with a communication function, wherein:
when the number of unavailable data calculated by the number-of-unavailable-data calculation unit is smaller than the number of simultaneously unavailable data due to communication trouble, retained in the unavailable data storage unit, the fault determining unit withholds determining of an open-circuit fault in the power distribution system.

10. The power distribution facilities management system according to claim 7, wherein:
the fault determining unit sends an open-circuit fault determination result to a substation that supplies electric power to the distribution system.

11. The power distribution facilities management system according to claim 7, wherein:
each of the sensors with a communication function is placed at an electric power consumer house connected to the distribution system, acquires meter-reading data at predetermined intervals of time, and has a function for communicating wirelessly with at least one other sensor with a communication function existing in a predetermined region.

12. The power distribution facilities management system according to claim 7, wherein:
the meter-reading data is at least one of electric power consumption, a voltage value, and a current value, detected at an electric power consumer house having one of the sensors with a communication function.

13. The power distribution facilities management system according to claim 7, wherein:
a meter-reading data collection unit collects the meter-reading data received from the sensors each having a communication function, the meter-reading data collection unit being placed in plurality for one feeder on the power distribution system, and having a function that uses wireless communication to collect at predetermined time intervals the meter-reading data measured by the metering devices placed within a predetermined region.

14. The power distribution facilities management system according to claim 8, wherein:
the system data storage unit retains data about a configuration of the distribution system, data about transformers installed on the distribution system, and data about interconnection between a transformer and metering devices each connecting thereto at a downstream section of the distribution system relative to the transformer.

15. The power distribution facilities management system according to claim 7, wherein:
the fault determining unit is configured to:
compare an unavailable state of the meter-reading data measured by each of the sensors with a communication function and an unavailable state of the meter-reading data that assumes an open circuit at a suitable location on the distribution system; and
when a determination index that is a rate of the two unavailable states of the meter-reading data reaches a predetermined value, determine an open circuit to have occurred in the distribution system.

16. The power distribution facilities management system according to claim 7, wherein:
the fault determining unit is configured to:
compare an unavailable state of the meter-reading data measured by each of the sensors with a communication function, and an unavailable state of the meter-reading data that assumes an open circuit in a line at a suitable location on the distribution system; and
when a combination of those sensors with a communication function that are involved in the former unavailable state agrees at a predetermined rate with a combination of metering devices involved in the latter unavailable state under the assumed open circuit in the line, determine an open circuit to have occurred at the assumed location.
